(19) United States
(12) Patent Application Publication
(10) Pub. No.: US 2021/0292226 A1
(43) Pub. Date: Sep. 23, 2021

(54) GLASS, CHEMICALLY STRENGTHENED GLASS, AND ELECTRONIC DEVICE INCLUDING SAME

(71) Applicant: AGC Inc., Tokyo (JP)

(72) Inventors: Takumi UMADA, Tokyo (JP); Kenji IMAKITA, Tokyo (JP); Yusuke ARAI, Tokyo (JP); Tatsuya MIYAJIMA, Tokyo (JP)

(73) Assignee: AGC Inc., Tokyo (JP)

(21) Appl. No.: 17/341,462

(22) Filed: Jun. 8, 2021

Related U.S. Application Data
(63) Continuation of application No. PCT/JP2019/047190, filed on Dec. 3, 2019.

(30) Foreign Application Priority Data
Dec. 11, 2018 (JP) 2018-231777

(51) Int. Cl. C03C 3/097; C03C 21/00; C03C 3/085; C03C 3/087; C03C 3/091; C03C 3/095; C03C 4/18; H05K 5/03

(52) U.S. Cl. CPC C03C 3/097; C03C 21/002; C03C 3/085; C03C 3/087; C03C 2204/00; C03C 3/095; C03C 4/18; H05K 5/03; C03C 3/091

(57) ABSTRACT

The present invention relates to a glass having a fracture toughness value of 0.85 MPa·m^{1/2} or more, and including, as represented by molar percentage based on oxides, 40% or more of SiO₂, 20% or more of Al₂O₃, 5% or more of Li₂O, and from 1 to 6% in total of one or more selected from Y₂O₃, La₂O₃ and Ga₂O₃. The present invention relates to a glass including, as represented by molar percentage based on oxides, from 40 to 60% of SiO₂, from 20 to 45% of Al₂O₃, and from 5 to 15% of Li₂O. Denoting the content of SiO₂ as [SiO₂] and the content of Al₂O₃ as [Al₂O₃], (2×[Al₂O₃]-X)/[SiO₂] is 0 or more and 1 or less.

### TECHNICAL FIELD

The present invention relates to a chemically strengthened glass.

### BACKGROUND ART

A chemically strengthened glass is used for a cover glass, etc. of a portable terminal. The chemically strengthened glass is a glass obtained by, for example, a method of immersing a glass in a molten salt of sodium nitrate, etc. to effect ion exchange between alkali metal ions contained in the glass and alkali ions having a larger ionic radius contained in the molten salt, thereby forming a compressive stress layer in a surface of the glass.

Patent Literature 1 discloses a method of applying a two-step chemical strengthening treatment to an aluminosilicate glass containing lithium so as to obtain a chemically strengthened glass having a high surface strength and a large depth of compressive stress layer.

The chemically strengthened glass has a tendency that the strength gets higher as the surface compressive stress value or the depth of compressive stress layer increases. On the other hand, when a compressive stress layer is formed on the surface, an internal tensile stress is generated inside the glass according to the total amount of compressive stresses. If the internal tensile stress value (CT) exceeds a certain threshold, fracture occurs violently when the glass is broken. This threshold value is also referred to as a CT limit.

Patent Literature 2 discloses a high-strength glass having high crack resistance. This high-strength glass contains a large amount of Al₂O₃ and is manufactured by a special method called a containerless method. In addition, the glass described specifically in Patent Literature 2 is a binary glass composed of SiO₂ and Al₂O₃ and therefore, cannot be chemically strengthened.

### CITATION LIST

### Patent Literature

Patent Literature 1: JP-T-2013-536155 (the term “JP-T” as used herein means a published Japanese translation of a PCT patent application)

Patent Literature 2: JP-A-2016-50155

### SUMMARY OF INVENTION

### Technical Problem

An object of the present invention is to provide a glass having a high fracture toughness value and being easy to manufacture.

Also, an object of the present invention is to provide a chemically strengthened glass resisting the occurrence of violent crushing while having high strength.

### Solution to Problem

The present inventors made studies on the CT limit for a chemically strengthened glass and found that the CT limit tends to increase as the fracture toughness value is larger. Then, they have thought that as long as the glass has excellent chemical strengthening characteristics and a large fracture toughness value, high strength can be realized by chemical strengthening while preventing violent crushing. In addition, as a result of studies, it has been found that even if the glass is not a binary glass composed of SiO₂ and Al₂O₃, a high fracture toughness value can be realized.

The present invention provides a glass having a fracture toughness value of 0.85 MPa·m^{1/2} or more and containing, as represented by molar percentage based on oxides, 40% or more of SiO₂, 20% or more of Al₂O₃, 5% or more of Li₂O, and from 1 to 6% in total of one or more selected from Y₂O₃, La₂O₃ and Ga₂O₃.

The present invention provides a glass containing, as represented by molar percentage based on oxides, from 40 to 60% of SiO₂, from 20 to 45% of Al₂O₃, and from 5 to 15% of Li₂O, wherein denoting the content of SiO₂ as [SiO₂] and the content of Al₂O₃ as [Al₂O₃], (2x[Al₂O₃]-X)/[SiO₂] is 0 or more and 1 or less.

Here, X is represented by the following formula:

X=2×M1+2×M2+6×M3+4×M4+10×M5+6×M6

wherein M1 (%) is the total of the contents of oxides selected from Li₂O, Na₂O, K₂O and P₂O₅, M2 (%) is the total of the contents of MgO, CaO, SrO, ZnO and BaO, M3 (%) is the total of the contents of Y₂O₃, La₂O₃ and Ga₂O₃, M4 (%) is the content of TiO₂, M5 (%) is the total of the contents of V₂O₅, Ta₂O₅ and Nb₂O₅, and M6 (%) is the content of WO₃.

The present invention provides a chemically strengthened glass having a compressive stress value (CS₅₀) at a depth of 50 μm from the glass surface of 150 MPa or more, and

containing, as represented by molar percentage based on oxides, from 40 to 60% of SiO₂, from 20 to 45% of Al₂O₃, from 5 to 15% of Li₂O, and from 1 to 6% in total of one or more selected from Y₂O₃, La₂O₃ and Ga₂O₃.

The present invention provides a cover glass including the chemically strengthened glass above.

Furthermore, the present invention provides an electronic device including the cover glass above.

### Advantageous Effects of Invention

According to the present invention, a glass having a high fracture toughness value and being easy to manufacture is obtained. Also, a chemically strengthened glass resisting occurrence of violent crushing while having high strength is obtained.

### BRIEF DESCRIPTION OF DRAWINGS

FIG. 1 is a diagram illustrating the relationship between the internal tensile stress value (CT) after chemical strengthening of the glass and the crushing number with respect to two kinds of glasses.

FIG. 2 is a diagram plotting the relationship between the ratio of the number of pentacoordinate aluminums to the number of all aluminums determined by NMR measurement and the fracture toughness value with respect to glasses of Example and Comparative Example.

FIG. 3 illustrates a stress profile; the solid line is an example of the stress profile of the chemically strengthened glass of the present invention, and the dotted line is an example of the stress profile of the conventional chemically strengthened glass.

FIG. 4 is an example of the stress profile of the chemically strengthened glass of the present invention.

FIG. 5 is a diagram illustrating an example of the electronic device including the chemically strengthened glass of the present invention.

### DESCRIPTION OF EMBODIMENTS

In the present description, the numerical range expressed using “to” is used in the sense of including the numerical values before and after “to” as the lower limit value and the upper limit value. In the present description, the “to” is hereinafter used in the same sense unless otherwise indicated.

In the present description, the “stress profile” indicates a profile expressing the compressive stress value using, as a variable, the depth from the glass surface. In addition, the “depth of compressive stress layer (DOL)” is a depth at which the compressive stress value (CS) becomes 0. The “internal tensile stress value (CT)” indicates a tensile stress value at a depth corresponding to ½ of the sheet thickness t of the glass.

The stress profile in the present description is measured by a birefringence stress meter using a sample prepared by thinning a cross-section of a chemically strengthened glass. The birefringence stress meter is a device of measuring the magnitude of a stress-induced retardation by using a polarizing microscope and a liquid crystal compensator, etc. and includes, for example, a birefringence imaging system, Abrio-IM, manufactured by CRi, Inc.

The compressive stress value in a glass sheet surface layer portion can sometimes be measured using an optical-waveguide surface stress meter (for example, FSM-6000, manufactured by Orihara Industrial Co., Ltd.). According to the optical-waveguide surface stress meter, the stress value can be measured without applying a processing such as thinning of a glass sample. However, unless the refractive index decreases from the surface toward the inside, the optical-waveguide surface stress meter cannot measure the stress in measurement principle. Consequently, in the case where an aluminosilicate glass containing lithium is chemically strengthened, there is a problem that the compressive stress inside the glass sheet cannot be measured.

The stress value inside the glass sheet can sometimes be measured using a scattered-light photoelastic stress meter (for example, SLP-1000, manufactured by Orihara Industrial Co., Ltd.). According to the scattered-light photoelastic stress meter, the stress value can be measured without applying a processing such as thinning of a glass sample, irrespective of the refractive index distribution inside the glass. However, the scattered-light photoelastic stress meter is susceptible to the surface scattered light and therefore, it is difficult to exactly measure the stress value near the glass surface.

In the present description, the CT limit is the maximum value of CT when the crushing number as measured according to the following procedure becomes 10 or less.

As to the glass sheet for testing, a plurality of test glass sheets having a dimension of a 15 mm square and a thickness of 0.5 mm or more and 1 mm or less obtained by subjecting a glass with a mirror-finished surface to a chemical strengthening treatment under various conditions to have different CT values, are prepared. The CT value here can be measured using a scattered-light photoelastic stress meter.

Also, the depth of compressive stress layer (DOL) is estimated. If the DOL is too large relative to the thickness of the glass sheet, the glass composition of the tensile stress layer is changed, and the CT limit may not be correctly evaluated. Accordingly, a glass sheet having DOL of 100 μm or less is preferably used in the following test.

Using a Vickers tester, a Vickers indenter having a tip angle of 900 is struck into a central part of the test glass sheet to break the glass sheet, and the number of fragments is defined as the crushing number (when the glass sheet is broken into two pieces, the crushing number is 2). In the case where very fine fragments are generated, the number of fragments failing in passing through a 1-mm sieve is counted and taken as the crushing number.

However, when the crushing number exceeds 50, the crushing number may be regarded as 50. Because, for example, when the crushing number is too large, almost all fragments pass though the sieve, making it difficult to exactly count the number of fragments, and in practice, the effect on the evaluation of the CT limit is small. In addition, in the case where the test is started with an indentation load of the Vickers indenter of 3 kgf and the glass sheet is not broken, the indentation load is increased by steps of 1 kgf, and by repeating the test until the glass sheet is broken, the crushing number at the first breaking is counted.

The crushing number is plotted relative to the CT value of the test glass sheet, and the CT value at a point where the crushing number becomes 10 is read and taken as the CT limit.

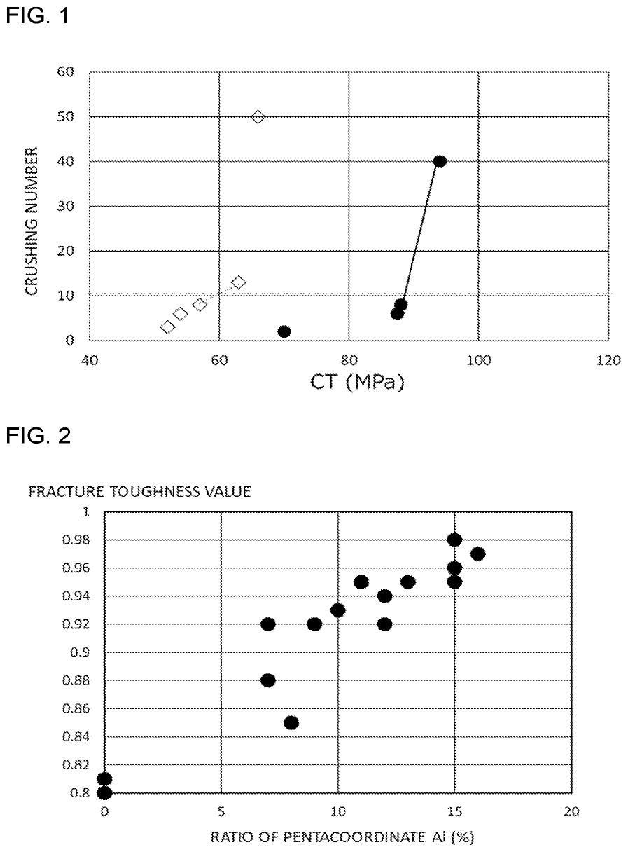

FIG. 1 is a diagram plotting the CT value and the crushing number with respect to glass A and glass B having different glass compositions. Glass A is plotted with white-outlined rhombus, and glass B is plotted with black circle. It is seen from FIG. 1 that as long as the glass has the same composition, the crushing number increases as the CT becomes larger. It is also seen that when the crushing number exceeds 10, the crushing number increases rapidly due to an increase in CT.

From a CT value when the crushing number takes as large a value as possible within the range of 10 or less and a CT value when the crushing number is more than 10 and takes as small a value as possible, a CT value when the crushing number becomes 10 is read and taken as the CT limit. At this time, the as large a value as possible in the range of 10 or less, which the crushing number takes, is 8 or more, preferably 9 or more. The crushing number at a point where the crushing number is more than 10 may be 40 or less and is more preferably 20 or less.

The measurement results with respect to glass A and glass B are shown in Table 1. As for glass A, from a CT value of 57 MPa when the crushing number is 8 and a CT value of 63 MPa when the crushing number is 13, the CT limit is determined as 60 MPa. As for glass B, from a CT value of 88 MPa when the crushing number is 8 and a CT value of 94 MPa when the crushing number is 40, the CT limit is determined as 88 MPa.

TABLE 1

| | CT | Crushing | CT Limit |
|---|---|---|---|
| | (MPa) | Number | (MPa) |
| Glass A | 52 | 3 | 60 |
| | 54 | 6 | |
| | 57 | 8 | |
| | 63 | 13 | |
| | 66 | 50 | |
| Glass B | 70 | 2 | 88 |
| | 87 | 6 | |
| | 88 | 8 | |
| | 94 | 40 | |

In the present description, the “chemically strengthened glass” indicates a glass after a chemical strengthening treatment is applied, and the “glass for chemical strengthening” indicates a glass before a chemical strengthening treatment is applied.

In the present description, the “base composition of a chemically strengthened glass” indicates a glass composition of a glass for chemical strengthening. In the chemically strengthened glass, except for the case where an extreme ion exchange treatment is applied, the glass composition at a depth corresponding to ½ of the sheet thickness t is the base composition of the chemically strengthened glass.

In the present description, unless otherwise specified, the glass composition is expressed as a molar percentage on an oxide basis, and the mol % is written as “%” simply.

Also, in the present description, the “contains substantially no” means to be below the level of impurities contained in raw materials, etc., that is, to be not intentionally incorporated. Specifically, the content is, for example, less than 0.1 mol %.

### <Glass>

First, the glass before chemical strengthening (glass for chemical strengthening) is described.

The present glass may be a glass (first glass) having a fracture toughness value of 0.85 MPa·m^{1/2} or more, containing, as represented by molar percentage based on oxides, 40% or more of SiO₂, 20% or more of Al₂O₃, and 5% or more of Li₂O, and containing from 1 to 6% in total of one or more selected from Y₂O₃, La₂O₃ and Ga₂O₃.

The present glass may also be a glass (second glass) containing, as represented by molar percentage based on oxides, from 40 to 60% of SiO₂, from 20 to 45% of Al₂O₃, and from 5 to 15% of Li₂O, in which the later-described (2×[Al₂O₃]-X)/[SiO₂] is 0 or more and 1 or less.

In the case where the present glass for chemical strengthening is in a sheet shape, from the viewpoint of increasing the effects of chemical strengthening, the sheet thickness (t) is, for example, 2 mm or less, preferably 1.5 mm or less, more preferably 1 mm or less, still more preferably 0.9 mm or less, yet still more preferably 0.8 mm or less, and most preferably 0.7 mm or less. For obtaining sufficient strength, the sheet thickness is, for example, 0.1 mm or more, preferably 0.2 mm or more, more preferably 0.4 mm or more, still more preferably 0.5 mm or more.

The fracture toughness value of the present glass is preferably 0.85 MPa·m¹² or more. A glass having a large fracture toughness value has a large CT limit and therefore, even when a large surface compressive stress layer is formed by chemical strengthening, violent crushing is less likely to occur. The fracture toughness value is more preferably 0.9 MPa·m^{1/2} or more, still more preferably 0.95 MPa·m^{1/2} or more. Also, the fracture toughness value is usually 2.0 MPa·m^{1/2} or less and typically, 1.5 MPa·m^{1/2} or less.

The fracture toughness value can be measured using, for example, the DCDC method (Acta metall. mater. Vol. 43, pp. 3453-3458, 1995).

The above-described CT limit is preferably 75 MPa or more, more preferably 78 MPa or more, still more preferably 80 MPa or more. The CT limit of the present glass is usually 95 MPa or less.

The present glass is a lithium aluminosilicate glass, specifically, a glass containing 40% or more of SiO₂, 20% or more of Al₂O₃, and 5% or more of Li₂O. Since the lithium aluminosilicate glass contains lithium ions which are an alkali ion having a smallest ionic radius, a chemically strengthened glass having a desirable stress profile is obtained by a chemical strengthening treatment where ion exchange is effected using various molten salts.

In the present glass, (2×[Al₂O₃]-X)/[SiO₂] is preferably 0 or more and 1 or less. Here, [SiO₂] is the SiO₂ content expressed as mol %, and [Al₂O₃] is the Al₂O₃ content also expressed as mol %. In the following, other components are expressed in the same manner.

Denoting as M1 (%) the total ([Li₂O]+[Na₂O]+[K₂O]+[P₂O₅]) of the contents of oxides selected from Li₂O, Na₂O, K₂O and P₂O₅, as M2 (%) the total ([MgO]+[CaO]+[SrO]+[ZnO]+[BaO]) of the contents of MgO, CaO, SrO, ZnO and BaO, as M3 (%) the total ([Y₂O₃]+[La₂O₃]+[Ga₂O₃]+[Cr₂O₃]) of the contents of Y₂O₃, La₂O₃, Ga₂O₃ and Cr₂O₃, as M4 (%) the content [TiO₂] of TiO₂, as M5 (%) the total ([V₂O₅]+[Ta₂O₅]+[Nb₂O₅]) of the contents of V₂O₅, Ta₂O₅ and Nb₂O₅, and as M6 (%) the content [WO₃] of WO₃, X is represented by the following formula:

X=2×M1+2×M2+6×M3+4×M4+10×M5+6×M6

The present inventors thought that the value of (2×[Al₂O₃]-X) serves as an indication of the amount of aluminum ions uninfluenced by the charges from ions on the periphery. Although aluminum ions uninfluenced by the charges are likely to have a pentacoordinate structure, if an excessively large number of such ions are present, vitrification is difficult. Then, they thought that when the value of (2×[Al₂O₃]-X)/[SiO₂] is 0 or more and 1 or less, the fracture toughness value becomes large. The value of (2×[Al₂O₃]-X)/[SiO₂] is preferably 0.2 or more and 0.8 or less.

The reason therefor is described below.

The aluminum ion is known to usually have mainly a tetracoordinate structure in an aluminosilicate glass. However, it is supposed that the aluminum ion takes on a pentacoordinate structure in a binary glass of SiO₂-Al₂O₃ and a high fracture toughness value is obtained in a glass where a large amount of aluminum ions having a pentacoordinate structure are present (Scientific Reports, Vol. 6, 23620, 2016). The aluminum ion having a pentacoordinate structure is considered to take on a tetracoordinate structure upon receiving charge donation from other ions, etc.

Then, the present inventors have considered as follows.

In the case of adding other components to a binary glass of SiO₂-Al₂O₃ in which a large amount of aluminum ions having a pentacoordinate structure are present, for example, monovalent cations such as lithium, sodium and potassium each may donate one charge to change one aluminum ion from a pentacoordinate structure to a tetracoordinate structure. When the total of the contents of Li₂O, Na₂O and K₂O is denoted as M1, 2×M1 aluminum ions may be changed to tetracoordination by 2×M1 monovalent cations.

A divalent cation such as magnesium, calcium and strontium may donate two charges to change two aluminum ions to a tetracoordinate structure. Then, when the total of the contents of MgO, CaO, SrO, ZnO and BaO is denoted as M2, 2×M2 aluminum ions may be changed to have a tetracoordinate structure.

It is considered that the same holds true for trivalent to hexavalent cations. More specifically, when a cation having a large valence, except for silicon, is present, the aluminum ion may likely take a tetracoordinate structure. Therefore, the X value above represents a total of valences of so-called network modifier cations (modifier cation). However, as for P, the cation is dealt with just like a monovalent cation. Because, in the case where P₂O₅ and Al₂O₃ are contained in the glass, the effect of donating electrons from a double bond between P=O to Al and thereby changing both P and Al to tetracoordination is large.

The presence of a pentacoordinate aluminum can be confirmed by nuclear magnetic resonance (NMR) spectrum. The present inventors measured the amount of pentacoordinate aluminum in the glass by using NMR and have found that the fracture toughness value tends to increase as the ratio of pentacoordinate aluminum is larger. FIG. 2 is a diagram plotting the relationship between the ratio of pentacoordinate aluminum determined by NMR measurement and the fracture toughness value with respect to glasses of Example and Comparative Example described later.

From the viewpoint of increasing the fracture toughness value, the ratio of the number of pentacoordinate aluminums to the number of all aluminums in the glass is preferably 9% or more, more preferably 10% or more, still more preferably 12% or more. The ratio of the number of pentacoordinate aluminums is usually 20% or less and typically 18% or less.

The present inventors have also found that as the amount of Al₂O₃ in the glass composition is larger or as the amount of Y₂O₃ is larger, the number of tetracoordinate aluminums decreases and the ratio of the number of pentacoordinate aluminums increases.

The glass of the present invention preferably contains

from 40 to 60% of SiO₂,

from 20 to 45% of Al₂O₃,

from 5 to 15% of Li₂O, and

from 1 to 6% in total of one or more selected from Y₂O₃, La₂O₃ and Ga₂O₃.

The preferable glass composition is described below.

In the present glass, SiO₂ is a component constituting a glass network structure and is a component enhancing the chemical durability. In order to obtain sufficient chemical durability, the content of SiO₂ is preferably 40% or more, more preferably 44% or more, still more preferably 48% or more. In order to increase the strength of the glass, the content of SiO₂ is preferably 60% or less, more preferably 58% or less, still more preferably 55% or less.

Al₂O₃ is an essential component of the present glass and is a component contributing to achieving high strength of the glass. In order to obtain sufficient strength, the content of Al₂O₃ is preferably 20% or more, more preferably 24% or more, still more preferably 28% or more. For increasing the meltability, the content of Al₂O₃ is preferably 45% or less, more preferably 40% or less, still more preferably 35% or less.

Li₂O is an essential component of a lithium aluminosilicate glass. In order to increase the depth of compressive stress layer DOL by chemical strengthening, the content of Li₂O is preferably 5% or more, more preferably 7% or more, still more preferably 8% or more.

In order to prevent the occurrence of devitrification during glass production or at the time of performing bending process, the content of Li₂O is preferably 15% or less, more preferably 13% or less, still more preferably 12% or less.

All of Y₂O₃, La₂O₃ and Ga₂O₃ are not an essential component, but in order to increase the solubility, it is preferable to contain any one or more thereof. The total [Y₂O₃]+[La₂O₃]+[Ga₂O₃] of the contents of Y₂O₃, La₂O₃ and Ga₂O₃ is preferably 1% or more, more preferably 2% or more, still more preferably 3% or more. [Y₂O₃]+[La₂O₃] is preferably 1% or more, more preferably 2% or more, or 3% or more.

In order to maintain high strength, [Y₂O₃]+[La₂O₃]+[Ga₂O₃] is preferably 6% or less, more preferably 5.5% or less, still more preferably 5% or less. [Y₂O₃]+[La₂O₃] is more preferably 6% or less, still more preferably 5.5% or less, or 5% or less.

In order to increase the solubility, the present glass preferably contains Y₂O₃. The content of Y₂O₃ is preferably 1% or more, more preferably 2% or more, still more preferably 3% or more.

In order to increase the strength of the glass, the content of Y₂O₃ is preferably 6% or less, more preferably 5.5% or less, still more preferably 5% or less.

Na₂O is not essential but is a component forming a surface compressive stress layer by ion exchange utilizing a molten salt containing potassium and is also a component enhancing the meltability of the glass. The content of Na₂O is preferably 0.5% or more, more preferably 1% or more, still more preferably 1.5% or more. The content of Na₂O is preferably 10% or less, more preferably 8% or less, still more preferably 6% or less.

K₂O is not essential but may be contained so as to enhance the meltability of the glass and prevent devitrification. The content of K₂O is preferably 0.5% or more, more preferably 1% or more. In order increase the compressive stress value by ion exchange, the content of K₂O is preferably 5% or less, more preferably 3% or less, still more preferably 1% or less.

Alkali metal oxides such as Li₂O, Na₂O and K₂O (sometimes collectively referred to as R₂O) all are a component lowering the melting temperature of the glass, and it is preferable to contain 5% or more in total of these. The total R₂O of the contents of alkali metal oxides is preferably 5% or more, more preferably 7% or more, still more preferably 8% or more. In order to maintain the strength of the glass, R₂O is preferably 20% or less, more preferably 18% or less.

In order to obtain sufficient strength, the ratio [Li₂O]/[R₂O] of [Li₂O] denoting the content of Li₂O to [R₂O] denoting the total content of alkali metal oxides is preferably 0.8 or more, more preferably 0.85 or more. [Li₂O]/[R₂O] is 1 or less and in order to increase the solubility, more preferably 0.95 or less.

Alkaline earth metal oxides such as MgO, CaO, SrO, BaO and ZnO all are a component enhancing the meltability of the glass but tend to decrease the ion exchange performance. The total (MgO+CaO+SrO+BaO+ZnO) of the contents of MgO, CaO, SrO, BaO, and ZnO is preferably 15% or less, more preferably 10% or less, still more preferably 5% or less.

Among alkaline earth metal oxides, MgO tends to increase the effect of chemical strengthening when contained. In the case of containing MgO, the content thereof is preferably 0.1% or more, more preferably 0.5% or more, and is preferably 10% or less, more preferably 8% or less, still more preferably 5% or less.

In the case of containing CaO, the content thereof is preferably 0.5% or more, more preferably 1% or more. In order to enhance the ion exchange performance, the content is preferably 5% or less, more preferably 3% or less.

In the case of containing SrO, the content thereof is preferably 0.5% or more, more preferably 1% or more. In order to enhance the ion exchange performance, the content is preferably 5% or less, more preferably 3% or less.

In the case of containing BaO, the content thereof is preferably 0.5% or more, more preferably 1% or more. In order to enhance the ion exchange performance, the content is preferably 5% or less, more preferably 1% or less, and it is still more preferable to be substantially free of this component.

ZnO is a component enhancing the meltability of the glass and may be contained. In the case of containing ZnO, the content thereof is preferably 0.2% or more, more preferably 0.5% or more. In order to increase the weather resistance of the glass, the content of ZnO is preferably 5% or less, more preferably 3% or less.

B₂O₃ is not essential but may be added so as to, for example, enhance the meltability during glass production. When a chemically strengthened glass is made, this component decreases the slope of a stress profile near the surface of the chemically strengthened glass and thereby increases the stability. Accordingly, the content of B₂O₃ is preferably 0.5% or more, more preferably 1% or more, still more preferably 2% or more.

B₂O₃ is a component readily allowing stress relaxation after chemical strengthening and therefore, in order to more increase the surface compressive stress of the chemically strengthened glass, the content is preferably 10% or less, more preferably 8% or less, still more preferably 5% or less, and most preferably 3% or less.

P₂O₅ may be contained so as to enhance the ion exchange performance. In the case of containing P₂O₅, the content thereof is preferably 0.5% or more, more preferably 1% or more. In order to increase the chemical durability, the content of P₂O₅ is preferably 10% or less, more preferably 5% or less, still more preferably 3% or less.

TiO₂ tends to prevent broken pieces from scattering upon breakage of the chemically strengthened glass and may be contained. In the case of containing TiO₂, the content thereof is preferably 0.1% or more. In order to prevent devitrification during melting, the content of TiO₂ is preferably 5% or less, more preferably 3% or less, still more preferably 1% or less, and it is particularly preferable to be substantially free of this component.

ZrO₂ tends to increase the surface compressive stress of the chemically strengthened glass and may be contained. In the case of containing ZrO₂, the content thereof is preferably 0.5% or more, more preferably 1% or more. Also, in order to prevent devitrification during melting, the content is preferably 5% or less, more preferably 3% or less, still more preferably 2% or less.

The total (TiO₂+ZrO₂) of the contents of TiO₂ and ZrO₂ is preferably 5% or less, more preferably 3% or less. (TiO₂+ZrO₂) is preferably 0.5% or more, more preferably 1% or more.

Nb₂O₅ and Ta₂O₅ may be contained so as to, for example, suppress crushing of the chemically strengthened glass. In the case of containing these components, for the total content thereof, each of Nb₂O₅ and Ta₂O₅ is preferably 0.5% or more, more preferably 1% or more, still more preferably 1.5% or more, yet still more preferably 2% or more. Each of the contents is preferably 3% or less, more preferably 2% or less.

In the case of coloring the glass, a coloring component may be added to the extent not impeding the attainment of desired chemical strengthening characteristics. The coloring component includes, for example, Co₃O₄, MnO₂, Fe₂O₃, NiO, CuO, Cr₂O₃, V₂O₅, Bi₂O₃, SeO₂, CeO₂, Er₂O₃, and Nd₂O₃. One of these may be used alone, or some of them may be used in combination.

The total content of the coloring components is preferably 7% or less. Within this range, the devitrification of the glass can be prevented. The content of the coloring components is more preferably 5% or less, still more preferably 3% or less, yet still more preferably 1% or less. In the case of intending to increase the transparency of the glass, it is preferable to be substantially free of these components.

SO₃, chlorides, fluorides, etc. may be appropriately contained as a refining agent at the time of melting of the glass. Preferably, As₂O₃ is substantially not contained. In the case of containing Sb₂O₃, the content thereof is preferably 0.3% or less, more preferably 0.1% or less, and it is most preferable to be substantially free of this component.

The liquidus temperature of the present glass is preferably 1,670° C. or less, more preferably 1,650° C. or less. Due to the low liquidus temperature, the glass can be manufactured without using a special method such as containerless method.

As for the high temperature viscosity of the present glass, for example, log η at 1,650° C. is 2 or less.

The softening point of the present glass is preferably 1,000° C. or less, more preferably 950° C. or less. Because, as the softening point of the glass is lower, the heat treatment temperature when performing bend forming is lower, and not only the energy consumption decreases but also the load on equipment is reduced. A glass with an excessively low softening point has a tendency that a stress introduced at the time of chemical strengthening treatment is readily relaxed and the strength is easily reduced. Therefore, the softening point is preferably 550° C. or more, more preferably 600° C. or more, still more preferably 650° C. or more.

The softening point can be measured by a fiber elongation method according to JIS R3103-1:2001.

The present glass can be manufactured by a conventional method. For example, raw materials of respective components of the glass are heated and melted in a glass melting furnace. Thereafter, the molten glass is homogenized by a known method, formed into a desired shape such as glass sheet, and cooled.

After that, the shaped glass is ground and polished, if desired, to form a glass substrate. In the case of cutting the glass substrate into a predetermined shape and size or in the case of chamfering the glass substrate, when the cutting or chamfering of the glass substrate is performed before applying the later-described chemical strengthening treatment, a compressive stress layer is advantageously formed also in end faces by the subsequent chemical strengthening treatment.

The present glass is a glass having a large fracture toughness value and resisting breakage, nevertheless, is easy to manufacture, therefore, useful as a member for structures such as window glass. In addition, since the CT limit in the case of performing chemical strengthening is large, the present glass is excellent as a glass for chemical strengthening.

### <Chemically Strengthened Glass>

In the case where the chemically strengthened glass of the present invention is in a sheet shape, the sheet thickness (t) thereof is, for example, 2 mm or less, preferably 1.5 mm or less, more preferably 1 mm or less, still more preferably 0.9 mm or less, yet still more preferably 0.8 mm or less, and most preferably 0.7 mm or less. For obtaining sufficient strength, the sheet thickness is, for example, 0.1 mm or more, preferably 0.2 mm or more, more preferably 0.4 mm or more, still more preferably 0.5 mm or more.

In the present chemically strengthened glass, the compressive stress value (CS₅₀) at a depth of 50 m from the glass surface is large. CS₅₀ is preferably 200 MPa or more, more preferably 220 MPa or more, still more preferably 240 MPa or more. CS₅₀ is usually 150 MPa or less.

In the present chemically strengthened glass, the depth (DOL) at which the compressive stress value becomes 0 is preferably 100 μm or more. DOL is more preferably 110 μm or more, still more preferably 120 μm or more. If DOL is too large relative to the sheet thickness t, an increase in CT is caused, and therefore, DOL is preferably t/4 or less, more preferably t/5 or less. Specifically, for example, when the sheet thickness t is 0.8 mm, DOL is preferably 160 μm or less.

The surface compressive stress (CS₀) of the present chemically strengthened glass is preferably 500 MPa or more, more preferably 600 MPa or more, still more preferably 700 MPa or more. In order to prevent chipping upon impact, CS₀ is preferably 1,000 MPa or less, more preferably 900 MPa or less.

Denoting as SA [unit: MPa·μm] the integrated value of compressive stress from the glass sheet surface to a depth of 10 m and as SB [unit: MPa·μm] the integrated value of compressive stress from a depth of 10 μm to a depth (DOL) where the compressive stress becomes 0, SB/(SA×t) is preferably 5.0 mm⁻¹ or more. When SB/(SA×t) is 5.0 mm⁻¹ or more, the compressive stress in a relatively deep portion from the glass sheet surface increases and in turn, the breakage from collision can be effectively prevented. SB/(SA×t) is more preferably 6.0 mm⁻¹ or more.

Here, SA is preferably 4,000 MPa·μm or less, more preferably 3,500 MPa·μm or less, still more preferably 3,000 MPa·μm or less. In order to prevent flexural fracture, SA is preferably 1,000 MPa·μm or more, more preferably 1,500 MPa·μm or more, still more preferably 2,000 MPa·μm or more.

SB is preferably 12,000 MPa·μm or more, more preferably 14,000 MPa·μm or more, still more preferably 16,000 MPa·μm or more. If SB is too large, violent crushing occurs at the time of applying scratches, and therefore, it is preferably 22,000 MPa·μm or less, more preferably 20,000 MPa·μm or less. SB/(SA×t) is preferably 25.0 mm⁻¹ or less, more preferably 20.0 mm⁻¹ or less.

In the present chemically strengthened glass, for increasing the strength, SA+SB that is a value obtained by integrating compressive stress values in a depth direction from the glass surface to a depth at which the compressive stress value becomes 0 is preferably 15,000 MPa·μm or more, more preferably 17,000 MPa·μm or more.

If SA+SB exceeds the CT limit, violent breakage is likely to occur. Therefore, SA+SB is preferably smaller than the CT limit and is, specifically, for example, preferably 26,000 MPa·μm or less, more preferably 22,000 MPa·μm or less.

The surface compressive stress CS₀ can sometimes be measured by means of a surface stress meter (for example, FSM6000, manufactured by Orihara Industrial Co., Ltd.) utilizing photoelasticity. However, in the case where, for example, the Na content in the glass before chemical strengthening is small, the measurement by means of a surface stress meter is difficult.

In such a case, the magnitude of surface compressive stress may be estimated by measuring the bending strength. Because, the bending strength increases as the surface compressive stress is larger.

The bending strength can be evaluated by performing a four-point bending test using a strip specimen of 10 mm×50 mm under the conditions of an outer fulcrum distance of the support of 30 mm, an inter-fulcrum distance of 10 mm, and a crosshead speed of 0.5 mm/min. The number of specimens is, for example, 10.

The four-point bending strength of the present chemically strengthened glass is preferably 500 MPa or more, more preferably 600 MPa or more, still more preferably 700 MPa or more. The four-point bending strength of the present chemically strengthened glass is usually 1,000 MPa or less and typically 900 MPa or less.

The composition of the present chemically strengthened glass is, in the sheet thickness-direction central part, the same as the composition of the glass of the present invention. In addition, except that the alkali metal ion concentration is changed due to the chemical strengthening treatment, the composition as a whole is fundamentally the same as that of the glass of the present invention and therefore, its description is omitted.

The shape of the present glass may be a shape other than a sheet shape according to the product, use, etc. to which the glass is applied. The glass sheet may have an edging pattern differing in the circumferential thickness. The configuration of the glass sheet is not limited thereto and, for example, two main surfaces may not be parallel to each other, or the whole or part of one or both of two main surfaces may be a curved surface. More specifically, the glass sheet may be, for example, a warpage-free flat glass sheet or may be a curved glass sheet having a curved surface.

### <Manufacturing Method of Chemically Strengthened Glass>

The present chemically strengthened glass is obtained by chemically strengthening (ion exchange treatment) the glass (glass for chemical strengthening) of the present invention.

The chemical strengthening treatment may be performed, for example, by immersing the glass sheet in a molten salt of potassium nitrate, etc. heated at 360 to 600° C. for 0.1 to 500 hours. Here, the heating temperature of the molten salt is preferably from 375 to 500° C., and the immersing time of the glass sheet in the molten salt is preferably from 0.3 to 200 hours.

The molten salt for performing the chemical strengthening treatment includes, for example, a nitrate, a sulfate, a carbonate, and a chloride. Among these, the nitrate includes, for example, lithium nitrate, sodium nitrate, potassium nitrate, cesium nitrate, and silver nitrate. The sulfate includes, for example, lithium sulfate, sodium sulfate, potassium sulfate, cesium sulfate, and silver sulfate. The carbonate includes, for example, lithium carbonate, sodium carbonate, and potassium carbonate. The chloride includes, for example, lithium chloride, sodium chloride, potassium chloride, cesium chloride, and silver chloride. One of these molten salts may be used alone, or a plurality of kinds of them may be used in combination.

In the present invention, the treatment conditions of the chemical strengthening treatment are not particularly limited, and appropriate conditions may be selected in consideration of the composition (properties) of the glass, the kind of molten salt, desired chemical strengthening characteristics, etc.

Also, in the present invention, the chemical strengthening treatment may be performed only once, or a plurality of times of chemical strengthening treatment may be performed under two or more different conditions (multi-step strengthening). For example, while a chemical strengthening treatment is performed as the first-step chemical strengthening treatment under the conditions making DOL large and CS relatively small, a chemical strengthening treatment may thereafter be performed as the second-step chemical strengthening treatment under the conditions making DOL relative small and CS large. In this case, the internal tensile stress area (St) can be reduced while increasing CS in the outermost surface of the chemically strengthened glass and, as a result, the internal tensile stress (CT) can be kept low.

### <Cover Glass and Electronic Device>

The present chemically strengthened glass is particularly useful as a cover glass used in mobile electronic devices such as mobile phone, smartphone, personal digital assistant (PDA) and tablet terminal. Furthermore, it is useful as well for a cover glass of electronic devices not intended to be carried, such as television (TV), personal computer (PC) and touch panel. The present chemically strengthened glass is useful also as a building material such as windowpane, as a table top, as an interior etc. of automobiles, aircrafts, etc., and as a cover glass thereof.

The present chemically strengthened glass can be made in a shape other than a flat shape by performing bending or forming before or after the chemical strengthening and therefore, is useful also for usage such as housing having a curved surface shape.

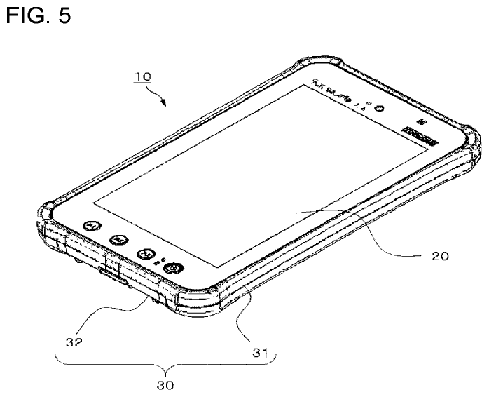

FIG. 5 is an example of the electronic device including the present chemically strengthened glass. The portable terminal 10 illustrated in FIG. 5 has a cover glass 20 and a housing 30. The housing 30 has a side surface 31 and a bottom surface 32. The present chemically strengthened glass is used for both the cover glass 20 and the housing 30.

The present invention is described below by referring to Examples, but the present invention is not limited thereto. Exs. 6 to 9 and 12 to 16 are Examples of the first glass, Exs. 3 to 9 and 12 to 16 are Examples of the second glass, and Exs. 1, 2, 10 and 11 are Comparative Examples. With respect to the results of each measurement in the Table, the blank indicates unmeasured.

### (Manufacture of Glass)

Glass raw materials were prepared to provide a glass composition shown as represented by molar percentage based on oxides in Tables 2 and 3 and subjected to a dissolution and polishing process so as to manufacture a glass sheet. Ex. 2 is glass A described above, and Ex. 6 is glass B.

As the glass raw material, general glass raw materials such as oxide, hydroxide and carbonate were appropriately selected and weighed to make 900 g of a glass.

The mixed glass materials were put into a platinum crucible, melted at 1,700° C. and defoamed. The resulting glass was poured on a carbon board to obtain a glass block, and the obtained glass block was polished to obtain a sheet-shaped glass having a sheet thickness of 0.8 mm.

### (Liquidus Temperature)

The glass was crushed and put into a platinum container and after the container was held in an electric furnace at 1,000° C. to 1,700° C. for 17 hours and then taken out, whether or not crystals are present was observed with an optical microscope.

### (Young's Modulus, Poisson Ratio)

The Young's modulus and Poisson's ratio were measured by an ultrasonic method.

### (Coordination Number of Al)

The ratio of the coordination number of aluminum atom in the glass was analyzed by NMR.

NMR Measurement conditions are described below.

Measuring device: Nuclear magnetic resonance apparatus ECZ900, manufactured by JEOL Ltd.

Resonant frequency: 156.38 MHz

Rotation speed: 20 kHz

Probe: for 3.2 mm solid

Flip angle: 30°

Pulse repetition delay: 1.5 sec

Measurement by a Single pulse method was performed, and α-Al₂O₃ was used as a secondary chemical shift reference at 16.6 ppm. With respect to the measurement results, phase correction and baseline correction were conducted using NMR Software Delta produced by JEOL Ltd., and fitting was then conducted using Gaussian functions so as to calculate the ratios of tetracoordination, pentacoordination and hexacoordination. Although the phase correction and baseline correction have high arbitrary property, the processing was appropriately performed by subtracting a spectrum for an empty cell not containing the sample. The peak fitting has high arbitrary property as well, but a good fitting was accomplished by setting a peak top in a range of 80 to 45 ppm for tetracoordination, setting a peak top in a range of 45 to 15 ppm for pentacoordination, setting a peak top in a range of 15 to −5 ppm for hexacoordination, and appropriately setting the peak width (not to exceed a ratio of 1.5 times at a maximum between respective coordination numbers). In the case of quantitatively evaluating the coordination number of Al by ²⁷Al MAS NMR spectrum, it is important to perform the measurement in a high magnetic field (22.3 T or more).

### (Fracture Toughness Value)

A sample of 6.5 mm×6.5 mm×65 mm was prepared, and the fracture toughness value was measured by the DCDC method. At this time, the evaluation was performed by boring a through hole of 2 mmϕ in the 65 mm×6.5 mm surface of the sample.

### (CT Limit)

With respect to the obtained sheet-shaped glass, the CT limit was measured by the method described above. More specifically, the sheet-shaped glass was chemically strengthened using a NaNO₃ salt or a KNO₃ salt under various conditions, the obtained chemically strengthened glass was measure for CT by using a scattered-light photoelastic stress meter (SLP-1000, manufactured by Orihara Industrial Co., Ltd.), and the crushing number was then measured by striking a Vickers indenter into the chemically strengthened glass sheets having different CT values so as to evaluate the CT limit.

### (Parameter X)

Denoting, as represented by molar percentage based on oxides, as M1 (%) the total of the contents of oxides selected from Li₂O, Na₂O, K₂O and P₂O₅, as M2 (%) the total of the contents of MgO, CaO, SrO, ZnO and BaO, as M3 (%) the total of the contents of Y₂O₃, La₂O₃ and Ga₂O₃, as M4 (%) the content of TiO₂, as M5 (%) the total of the contents of V₂O₅, Ta₂O₅ and Nb₂O₅, and as M6 (%) the content of WO₃, X was calculated according to the following formula:

X=2×M1+2×M2+6×M3+4×M4+10×M5+6×M6

### (Fracture Surface Energy)

The fracture surface energy y was evaluated according to the following formula. In the formula, K_{IC} is the fracture toughness value [unit: MPa·m^{1/2}], E is the Young's modulus [unit: GPa], and ν is the Poisson ratio.

$${K}_{IC} = {\{ \frac{2 E γ}{1 - {ν}^{2}} \}}^{1 / 2} \qquad [ Math . 1 ]$$

TABLE 2

| | Ex. 1 | Ex. 2 | Ex. 3 | Ex. 4 | Ex. 5 | Ex. 6 | Ex. 7 | Ex. 8 |
|---|---|---|---|---|---|---|---|---|
| SiO₂ | 70.0 | 70.4 | 50.0 | 47.6 | 47.6 | 53.6 | 50.8 | 50.8 |
| Al₂O₃ | 7.5 | 13.0 | 30.0 | 28.6 | 28.6 | 32.1 | 30.5 | 30.5 |
| Li₂O | 8.0 | 8.4 | 10.0 | 9.5 | 9.5 | 10.7 | 10.2 | 10.2 |
| Na₂O | 5.3 | 2.4 | 0.0 | 0.0 | 0.0 | 0.0 | 0.0 | 0.0 |
| K₂O | 1.0 | 0.0 | 0.0 | 0.0 | 0.0 | 0.0 | 0.0 | 0.0 |
| Y₂O₃ | 0.0 | 0.0 | 0.0 | 0.0 | 0.0 | 3.6 | 3.4 | 3.4 |
| La₂O₃ | 0.0 | 0.0 | 0.0 | 0.0 | 0.0 | 0.0 | 0.0 | 0.0 |
| Ga₂O₃ | 0.0 | 0.0 | 0.0 | 0.0 | 0.0 | 0.0 | 0.0 | |
| B₂O₃ | 0.0 | 1.8 | 0.0 | 4.8 | 0.0 | 0.0 | 0.0 | 5.1 |
| P₂O₅ | 0.0 | 0.0 | 0.0 | 0.0 | 4.8 | 0.0 | 5.1 | 0.0 |
| MgO | 7.0 | 2.8 | 10.0 | 9.5 | 9.5 | 0.0 | 0.0 | 0.0 |
| ZnO | 0.0 | 0.9 | 0.0 | 0.0 | 0.0 | 0.0 | 0.0 | 0.0 |
| CaO | 0.2 | 0.0 | 0.0 | 0.0 | 0.0 | 0.0 | 0.0 | 0.0 |
| ZrO₂ | 1.0 | 0.0 | 0.0 | 0.0 | 0.0 | 0.0 | 0.0 | 0.0 |
| CAl-free/CSi | −0.401 | −0.044 | 0.400 | 0.400 | 0.200 | 0.400 | 0.200 | 0.400 |
| Parameter X | 43.0 | 29.1 | 40.0 | 38.1 | 47.6 | 42.9 | 50.8 | |
| (2 × [Al₂O₃]-X)[SiO₂] | −0.401 | −0.044 | 0.400 | 0.400 | 0.200 | 0.400 | 0.200 | |
| [Li₂O]/[R₂O] | 0.56 | 0.77 | 1.00 | 1.00 | 1.00 | 1.00 | 1.00 | 1.00 |
| CT Limit (MPa) | 60 | 60 | 74 | 69 | 68 | 88 | 80 | 84 |
| Liquidus temperature (° C.) | 1100 | 1300 | 1690 | 1600 | 1660 | 1670 | 1550 | 1600 |
| Young's modulus (GPa) | 83 | 83 | 103 | 97 | 96 | 105 | 97 | 100 |
| Poisson ratio | 0.22 | 0.22 | 0.25 | 0.25 | 0.25 | 0.26 | 0.25 | 0.27 |
| Tetracoordinate Al | 100 | 100 | 88 | 91 | 93 | 83 | 86 | 89 |
| Pentacoordinate Al | 0 | 0 | 10 | 9 | 7 | 16 | 12 | 10 |
| Hexacoordinate Al | 0 | 0 | 2 | 0 | 0 | 1 | 2 | 1 |
| Fracture toughness value (MPa · m^{1/2)} | 0.84 | 0.84 | 1.04 | 0.97 | 0.95 | 1.23 | 1.12 | 1.18 |
| Fracture surface energy | 0.0041 | 0.0041 | 0.0049 | 0.0045 | 0.0044 | 0.0068 | 0.0061 | 0.0064 |

TABLE 3

| | Ex. 9 | Ex. 10 | Ex. 11 | Ex. 12 | Ex. 13 | Ex. 14 | Ex. 15 | Ex. 16 |
|---|---|---|---|---|---|---|---|---|
| SiO₂ | 52.6 | 51.7 | 53.6 | 53.6 | 56.5 | 59.9 | 51.4 | 53.6 |
| Al₂O₃ | 31.6 | 31.0 | 32.1 | 32.1 | 28.3 | 24.0 | 32.1 | 32.1 |
| Li₂O | 10.5 | 10.3 | 0.0 | 10.7 | 11.3 | 12.0 | 10.7 | 9.6 |
| Na₂O | 0.0 | 0.0 | 10.7 | 0.0 | 0.0 | 0.0 | 0.0 | 1.1 |
| K₂O | 0.0 | 0.0 | 0.0 | 0.0 | 0.0 | 0.0 | 0.0 | 0.0 |
| Y₂O₃ | 5.3 | 6.9 | 3.6 | 1.8 | 3.8 | 4.0 | 3.6 | 3.6 |
| La₂O₃ | 0.0 | 0.0 | 0.0 | 1.8 | 0.0 | 0.0 | 0.0 | 0.0 |
| Ga₂O₃ | 0.0 | 0.0 | 0.0 | 0.0 | 0.0 | 0.0 | 0.0 | 0.0 |
| B₂O₃ | 0.0 | 0.0 | 0.0 | 0.0 | 0.0 | 0.0 | 0.0 | 0.0 |
| P₂O₅ | 0.0 | 0.0 | 0.0 | 0.0 | 0.0 | 0.0 | 0.0 | 0.0 |
| MgO | 0.0 | 0.0 | 0.0 | 0.0 | 0.0 | 0.0 | 0.0 | 0.0 |
| ZnO | 0.0 | 0.0 | 0.0 | 0.0 | 0.0 | 0.0 | 0.0 | 0.0 |
| CaO | 0.0 | 0.0 | 0.0 | 0.0 | 0.0 | 0.0 | 0.0 | 0.0 |
| ZrO₂ | 0.0 | 0.0 | 0.0 | 0.0 | 0.0 | 0.0 | 0.0 | 0.0 |
| Parameter X | 52.6 | 62.1 | 42.9 | 43.0 | 45.2 | 47.9 | 43.0 | 43.0 |
| (2 × [Al₂O₃]-X)/[SiO₂] | 0.200 | 0.000 | 0.400 | 0.598 | 0.200 | 0.000 | 0.412 | 0.396 |
| [Li₂O]/[R₂O] | 1.00 | 1.00 | 0.00 | 1.00 | 1.00 | 1.00 | 1.00 | 0.90 |
| CT Limit (MPa) | 83 | 70 | 72 | 85 | 79 | 68 | 91 | 87 |
| Liquidus temperature (° C.) | 1630 | 1600 | 1650 | 1630 | 1400 | 1200 | 1640 | 1650 |
| Young's modulus (GPa) | 106 | 107 | 90 | 103 | 98 | 90 | 108 | 104 |
| Poisson ratio | 0.27 | 0.27 | 0.25 | 0.26 | 0.25 | 0.25 | 0.25 | 0.25 |
| Tetracoordinate Al | 83.00 | 87.00 | 92.00 | 85.00 | 86.00 | 91.00 | 88.00 | 84.00 |
| Pentacoordinate Al | 15.00 | 12.00 | 7.00 | 13.00 | 12.00 | 8.00 | 11.00 | 15.00 |
| Hexacoordinate Al | 2.00 | 1.00 | 1.00 | 2.00 | 2.00 | 1.00 | 1.00 | 1.00 |
| Fracture toughness value | 1.16 | 0.98 | 1.01 | 1.19 | 1.11 | 0.95 | 0.95 | 0.96 |
| (MPa · m^{1/2}) | | | | | | | | |
| Fracture surface energy | 0.0060 | 0.0042 | 0.0053 | 0.0064 | 0.0059 | 0.0047 | 00.0030 | 0.0042 |

### (Chemical Strengthening Treatment)

Glass sheets composed of glasses of Exs. 1, 6, 7 and 8 were chemically strengthened to obtain chemically strengthened glasses (Exs. 31 to 37). In the chemical strengthening, ions were exchanged under the conditions shown in the column of Treatment conditions 1 using the salt in the column of Molten salt 1 of Table 4 and thereafter, ions were exchanged under the conditions shown in the column of Treatment conditions 2 using the salt in the column of Molten salt 2.

Each of the obtained chemically strengthened glasses was processed into 0.3 mm×20 mm×sheet thickness and measured for the stress profile using a birefringence stress meter (a birefringence imaging system, Abrio-IM, manufactured by CRi, Inc.). Also, SA, SB, etc. were determined. SA is the integrated value [unit: MPa·μm] of compressive stress from the glass sheet surface to a depth of 10 μm, and SB is the integrated value [unit: MPa·μm] of compressive stress from a depth of 10 μm to a depth (DOL) where the compressive stress becomes 0.

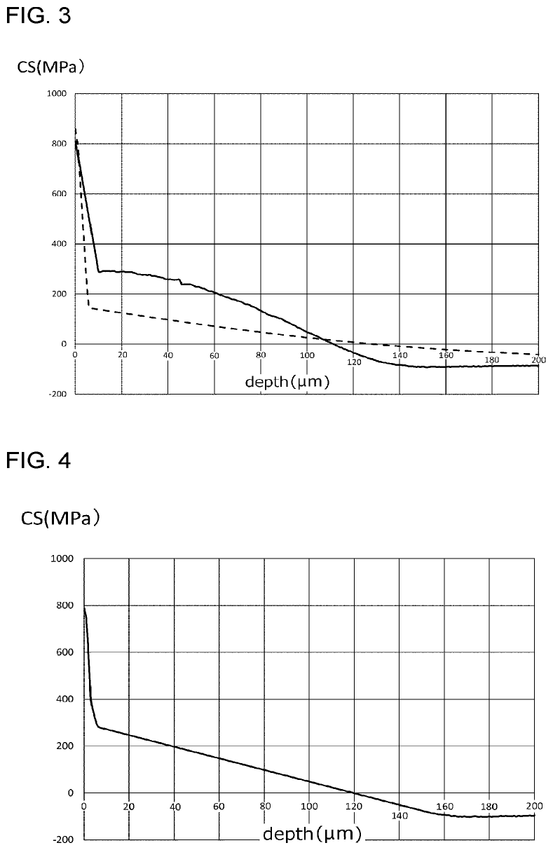

FIG. 3 illustrates the stress profiles of Ex. 31 and Ex. 32. In FIG. 3, the dotted line is Ex. 31, and the solid line is Ex. 32. FIG. 4 illustrates the stress profile of Ex. 38.

TABLE 4

| | Ex. 31 | Ex. 32 | Ex. 33 | Ex. 34 | Ex. 35 | Ex. 36 | Ex. 37 | Ex. 38 |
|---|---|---|---|---|---|---|---|---|
| Glass for | Ex. 1 | Ex. 6 | Ex. 6 | Ex. 7 | Ex. 7 | Ex. 8 | Ex. 8 | Ex. 16 |
| chemical | | | | | | | | |
| strengthening | | | | | | | | |
| Glass sheet | 0.8 | 0.8 | 0.8 | 0.8 | 0.8 | 0.8 | 0.8 | 0.8 |
| thickness (mm) | | | | | | | | |
| Molten salt 1 | NaNO₃ | NaNO₃ | NaNO₃ | NaNO₃ | NaNO₃ | NaNO₃ | NaNO₃ | NaNO₃ |
| Treatment | 450° C., | 450° C., | 450° C., | 450° C., | 450° C., | 450° C., | 450° C. | 450° C., |
| conditions 1 | 2 hr | 24 hr | 24 hr | 24 hr | 24 hr | 24 hr | 24 hr | 24 hr |
| Molten salt 2 | KNO₃ | KNO₃ | KNO₃ | KNO₃ | KNO₃ | KNO₃ | KNO₃ | KNO₃ |
| Treatment | 425° C., | 450° C., | 450° C., | 450° C., | 450° C., | 450° C., | 450° C., | 450° C., |
| conditions 2 | 1 hr | 12 hr | 6 hr | 12 hr | 6 hr | 12 hr | 6 hr | 12 hr |
| SA (MPa · μm) | 3255 | 2803 | 3159 | 2719 | 3101 | 2598 | 2910 | |
| SB (MPa · μm) | 7419 | 18575 | 21600 | 14678 | 16591 | 17921 | 20417 | |
| SB/(SA × t) | 2.8 | 8.3 | 8.5 | 6.7 | 6.7 | 8.6 | 8.8 | |
| (mm⁻¹) | | | | | | | | |
| SA + SB | | | | 17397 | 19692 | 20519 | 23327 | |
| (MPa · μm) | | | | | | | | |
| DOL (μm) | 129 | 111 | 101 | 130 | 115 | 117 | 106 | 130 |
| Surface | 860 | 229 | 260 | 250 | 232 | 251 | 207 | 850 |
| compressive | | | | | | | | |
| stress (MPa) | | | | | | | | |
| Compressive | 84 | 238 | 298 | 180 | 201 | 210 | 231 | 172 |
| stress at | | | | | | | | |
| depth of | | | | | | | | |
| 50 μm (MPa) | | | | | | | | |
| Four-point | 847 | 729 | 750 | 689 | 701 | 658 | 668 | 883 |
| bending | | | | | | | | |
| strength (MPa) | | | | | | | | |

It is understood that in Ex. 32, etc. using the glass for chemical strengthening of the present invention, not only the surface compressive stress and four-point bending strength are large but also the compressive stress at a depth of 50 m is large, and flexural fracture as well as breakage from collision are less likely to occur.

It is seen that in Ex. 31 where a conventional glass for chemical strengthening is strengthened, the four-point strength is high, but the compressive stress at a depth of 50 μm is small, and consequently, although flexural fracture is less likely to occur, breakage from collision tends to take place.

While the invention has been described in detail and with reference to specific embodiments thereof, it will be apparent to one skilled in the art that various changes and modifications can be made therein without departing from the spirit and scope of the invention. This application is based on Japanese Patent Application (Patent Application No. 2018-231777) filed on Dec. 11, 2018, the entirety of which is incorporated herein by way of reference. Also, all the references cited herein are incorporated herein in their entirety.

### REFERENCE SIGNS LIST

10 Portable terminal
20 Cover glass
30 Housing
31 Side surface
32 Bottom surface

1. A glass having a fracture toughness value of 0.85 MPa·m^{1/2} or more, and comprising, as represented by molar percentage based on oxides, 40% or more of SiO₂, 20% or more of Al₂O₃, 5% or more of Li₂O, and from 1 to 6% in total of one or more selected from Y₂O₃, La₂O₃ and Ga₂O₃.

2. The glass according to claim 1, comprising, as represented by molar percentage based on oxides, from 40 to 60% of SiO₂, from 20 to 45% of Al₂O₃, and from 5 to 15% of Li₂O.

3. A glass comprising, as represented by molar percentage based on oxides, from 40 to 60% of SiO₂, from 20 to 45% of Al₂O₃, and from 5 to 15% of Li₂O,
wherein denoting the content of SiO₂ as [SiO₂] and the content of Al₂O₃ as [Al₂O₃], (2×[Al₂O₃]-X)/[SiO₂] is 0 or more and 1 or less,
wherein X is represented by the following formula:
X=2×M1+2×M2+6×M3+4×M4+10×M5+6×M6,
wherein M1 (%) is a total of contents of oxides selected from Li₂O, Na₂O, K₂O and P₂O₅, M2 (%) is a total of contents of MgO, CaO, SrO, ZnO and BaO, M3 (%) is a total of contents of Y₂O₃, La₂O₃ and Ga₂O₃, M4 (%) is a content of TiO₂, M5 (%) is a total of contents of V₂O₅, Ta₂O₅ and Nb₂O₅, and M6 (%) is a content of WO₃.

4. The glass according to claim 1, wherein a ratio of the number of pentacoordinate aluminums to the number of all aluminums in the glass is 9% or more.

5. The glass according to claim 1, having a liquidus temperature of 1,670° C. or less.

6. The glass according to claim 1, wherein, as represented by molar percentage based on oxides, denoting the content of Li₂O as [Li₂O] and a total content of alkali metal oxides as [R₂O], [Li₂O]/[R₂O] is 0.8 to 1.

7. The glass according to claim 1, wherein a CT limit is 75 MPa or more, the CT limit being a maximum CT value when a crushing number is 10 or less.

8. A chemically strengthened glass having CS₅₀ which is a compressive stress value at a depth of 50 m from a glass surface of 150 MPa or more, and
comprising, as represented by molar percentage based on oxides, from 40 to 60% of SiO₂, from 20 to 45% of Al₂O₃, from 5 to 15% of Li₂O, and from 1 to 6% in total of one or more selected from Y₂O₃, La₂O₃ and Ga₂O₃.

9. The chemically strengthened glass according to claim 8, having the CS₅₀ of 200 MPa or more, and
having a DOL at which the compressive stress value becomes 0 of 100 μm or more.

10. The chemically strengthened glass according to claim 8, wherein an integrated value of the compressive stress in a depth direction from the glass surface to a depth at which the compressive stress value becomes 0 is 75 MPa or more.

11. A cover glass comprising the chemically strengthened glass according to claim 8.

12. An electronic device comprising the cover glass according to claim 11.

13. A method for producing a chemically strengthened glass, comprising chemically strengthening a glass for chemical strengthening comprising, as represented by molar percentage based on oxides, from 40 to 60% of SiO₂, from 20 to 45% of Al₂O₃, from 5 to 15% of Li₂O, and from 1 to 6% in total of one or more selected from Y₂O₃, La₂O₃ and Ga₂O₃ to obtain a chemically strengthened glass having CS₅₀ which is a compressive stress value at a depth of 50 m from a glass surface of 150 MPa or more.

14. The method according to claim 13,
wherein, as represented by molar percentage based on oxides, denoting the content of SiO₂ as [SiO₂] and the content of Al₂O₃ as [Al₂O₃], (2×[Al₂O₃]-X)/[SiO₂] is 0 or more and 1 or less,
wherein X is represented by the following formula:
X=2×M1+2×M2+6×M3+4×M4+10×M5+6×M6,
wherein M1 (%) is a total of contents of oxides selected from Li₂O, Na₂O, K₂O and P₂O₅, M2 (%) is a total of contents of MgO, CaO, SrO, ZnO and BaO, M3 (%) is a total of contents of Y₂O₃, La₂O₃ and Ga₂O₃, M4 (%) is a content of TiO₂, M5 (%) is a total of contents of V₂O₅, Ta₂O₅ and Nb₂O₅, and M6 (%) is a content of WO₃.

15. The method according to claim 13,
wherein, as represented by molar percentage based on oxides, denoting the content of Li₂O as [Li₂O] and a total content of alkali metal oxides as [R₂O], [Li₂O]/[R₂O] is 0.8 to 1.

16. The glass according to claim 3, wherein a ratio of the number of pentacoordinate aluminums to the number of all aluminums in the glass is 9% or more.

17. The glass according to claim 3, having a liquidus temperature of 1,670° C. or less.

18. The glass according to claim 3, wherein, as represented by molar percentage based on oxides, denoting the content of Li₂O as [Li₂O] and a total content of alkali metal oxides as [R₂O], [Li₂O]/[R₂O] is 0.8 to 1.

19. The glass according to claim 3, wherein a CT limit is 75 MPa or more, the CT limit being a maximum CT value when a crushing number is 10 or less.
